(19) United States
(12) Patent Application Publication
(10) Pub. No.: US 2008/0136464 A1
(43) Pub. Date: Jun. 12, 2008

(54) METHOD OF FABRICATING BIPOLAR TRANSISTORS AND HIGH-SPEED LVDS DRIVER WITH THE BIPOLAR TRANSISTORS

(75) Inventors: Kwi Dong KIM, Daejeon (KR); Chong Ki Kwon, Daejeon (KR); Jong Dae Kim, Daejeon (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon (KR)

(21) Appl. No.: 11/933,025

(22) Filed: Oct. 31, 2007

(30) Foreign Application Priority Data
Dec. 6, 2006 (KR) 10-2006-0122932
Jun. 12, 2007 (KR) 10-2007-0057137

(51) Int. Cl. H03K 3/00; H01L 21/8249

(52) U.S. Cl. 327/108; 438/234; 257/E21.696

(57) ABSTRACT

Provided is a differential signal driver capable of operating at a high speed at a low voltage of 1.8V. The differential signal driver includes: a differential-signal driving circuit for switching input differential signals and outputting a common mode voltage through first and second output nodes; and a common-mode feedback circuit for providing a predetermined current to the differential-signal driving circuit or receiving a predetermined current from the differential-signal driving circuit in response to the common mode voltage. The differential-signal driving circuit includes a common-mode voltage output circuit for connecting the first output node to the second output node and generating the common mode voltage of the differential-signal driving circuit. The differential input signals are received through two bipolar transistors.

### CROSS-REFERENCE TO RELATED APPLICATION

This application claims priority to and the benefit of Korean Patent Application Nos. 2006-122932, filed Dec. 6, 2006 and 2007-57137, filed Jun. 12, 2007, the disclosures of which are incorporated herein by reference in their entirety.

### BACKGROUND

1. Field of the Invention

The present invention relates to differential signal drivers, and more particularly, to a differential signal driver capable of operating at a high speed at a low voltage and bipolar transistors used in the differential signal driver.

The present invention has been produced from the work supported by the IT R&D program of MIC (Ministry of Information and Communication)/IITA (Institute for Information Technology Advancement) [2005-S-073-02, Development of semiconductor circuit design based on the nano-scaled device] in Korea.

2. Discussion of Related Art

Conventionally, a differential data transfer mode transfers data via a transfer signal made from a difference between voltage levels of two signal lines. Low-voltage differential signal drivers are generally used to match information data between electronic devices in the field of large-capacity information storage devices, high-performance computing devices, information/communication/household appliances, high-speed wired information communication devices, and so on.

FIG. 1 is a block diagram of a differential signal driver including general differential driver and receiver blocks.

As shown in FIG. 1, transmission lines 104 and 105, which have the same electrical characteristics as each other with an impedance of 50Ω, are connected between driver and receiver blocks 100 and 110. A signal is transferred through two transmission lines 104 and 105 that are balanced on transmission. Transmitting and receiving chips are connected to power source voltages 103 and 113, and a terminal resistor RT of a receiver chip 111 is set to 100Ω. The driver and receiver blocks 100 and 110 have driver and receiver chips 101 and 111, respectively, and input and output a signal through input and output terminals 102 and 112.

In the structure as described above, the driver chip 101 generates a differential signal by a potential difference between the two transmission lines 104 and 105 in response to an input signal from the input terminal 102. Then, the receiver chip 111 converts the differential signal, which is transferred through the transmission lines 104 and 105, into a signal of complementary metal-oxide-semiconductor (CMOS) level. The CMOS signal is output through the output terminal 112.

An operation of a low-voltage differential signal (LVDS) input/output (I/O) interface is as follows. If a current signal of 4 mA is output from a current source in the driver chip 101, the current signal is converted into a voltage signal of 400 mV through the terminal resistor R_{T} in the differential receiver block 110. The polarity and amplitude of the voltage signal is detected by the differential receiver block 110. When there is an input of the inverted data value, a current of the inverted polarity flows through the transmission lines 104 and 105 by the switching operation of the transmission stage (i.e., the driver block) 100. Then, a signal level is detected by changing a direction of the signal current I_{S}.

In such a constitution as shown in FIG. 1, the current of the driver chip 101 needs to flow at a constant rate as a static current, and the signal current I_{S} flowing through the transmission lines 104 and 105 also needs to flow at a constant rate without fluctuation.

FIG. 2 is a circuit diagram of the driver block 100 shown in FIG. 1. A static current is output from a static current circuit (not shown) and supplied to a differential-signal driving stage (or LVDS driving stage) 210 and a common mode feedback (CMFB) circuit 200 by way of transistors 221, 222, and 223. Transistors 211, 212, 213, and 214, as switching devices for changing current directions in the differential-signal driving stage 210, are turned on or off in response to polarity variations of input signals IN and INB of the driving stage 210, and settle a direction of the current flowing through the terminal resistor R_{T}. When changing the direction of the current flowing through the terminal resistor R_{T}, a potential difference is generated between the transmission lines 104 and 105, and thus a differential signal is output from the driving stage 210.

A reference voltage of 1.25V is output from a reference voltage generator (not shown) connected to a terminal V_{REF} and is compared to a voltage transmitted by feedback resistors 215 and 216 of the LVDS driving stage 210, and is applied to a gate of a transistor 230, thereby forming the CMFB circuit 200 to obtain a constant common mode voltage of the output signal.

A CMOS process is generally used to minimize power consumption of the transistors 211, 212, 213 and 214 as switching devices of the driving stage, but it has a disadvantage in that the rated current capacity of the MOS transistor is fully dependent on size (a ratio of width to length; W/L) of the device. In other words, the differential signal level is determined by a static current flowing through the differential-signal driving stage 210. In a general application, the differential-signal driving stage 210 uses a static current of 3.5 mA and a terminal resistance of 100Q. However, this is merely a case of a general application of maintaining a standardized LVDS electric signal level (250˜400 mV). When considering more advanced and diversified I/O interface environments, it may be insufficient to use a static current larger than 7 mV in I/O applications. Although there is a way of extending a permissible capacity of the rated current by enlarging the size (W/L) of the transistor device, it may cause voltage loss due to signal delay and parasitic resistance, which may result in limitation of signal swing level and an increase of the power source voltage. Furthermore, it is necessary to design the MOS field effect transistors (MOSFETs) to have a relatively large size (W/L) so as to optimize to a lower power source voltage and electrical standard and minimize a voltage over the parasitic resistance caused by the static current. However, it also causes enlargement of a device area of layout, increasing parasitic capacitance and generating an output delay. As a result, enlarging a chip area becomes a problem.

### SUMMARY OF THE INVENTION

The present invention is directed to a differential signal driver capable of operating at a high speed at a low voltage (e.g., 1.8V).

The present invention is also directed to a differential signal driver capable of operating at a high speed, in which field effect transistors as switching devices are replaced with bipolar transistors.

The present invention is further directed to a differential signal driver using bipolar transistors fabricated by a CMOS process without an additional mask.

One aspect of the present invention provides a method of fabricating a bipolar transistor and a field effect transistor on a substrate, the method including the steps of: forming a first-conductive first well region of the bipolar transistor deeper than a first-conductive third well region and a second-conductive fourth well region of the field effect transistor; and forming a second-conductive second well region, which is formed in the first well region, shallower than the third and fourth well regions, wherein the bipolar transistor has a different potential than the field effect transistor.

Another aspect of the present invention provides a high-speed low-voltage differential signal driver including: a differential-signal driving circuit for switching input differential signals and outputting a common mode voltage through first and second output nodes; and a common-mode feedback circuit for providing a predetermined current to the differential-signal driving circuit or receiving a predetermined current from the differential-signal driving circuit in response to the common mode voltage, wherein the differential-signal driving circuit comprises a common-mode voltage output circuit for connecting the first output node to the second output node and generating the common mode voltage of the differential-signal driving circuit, and wherein the differential signals are received through two bipolar transistors.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a block diagram of a differential signal driver including general differential driver and receiver blocks;

FIG. 2 is a circuit diagram of the differential driver block shown in FIG. 1;

FIG. 3 is a circuit diagram of a high-speed low-voltage differential signal driver according to an exemplary embodiment of the present invention;

FIG. 4 is a detailed circuit diagram of a high-speed low-voltage differential signal driver according to the exemplary embodiment of the present invention;

FIG. 5 is a waveform diagram showing output signal levels of the differential signal driver according to the exemplary embodiment of the present invention; and

FIG. 6 is a sectional diagram of a bipolar transistor fabricated by the exemplary embodiment of the present invention.

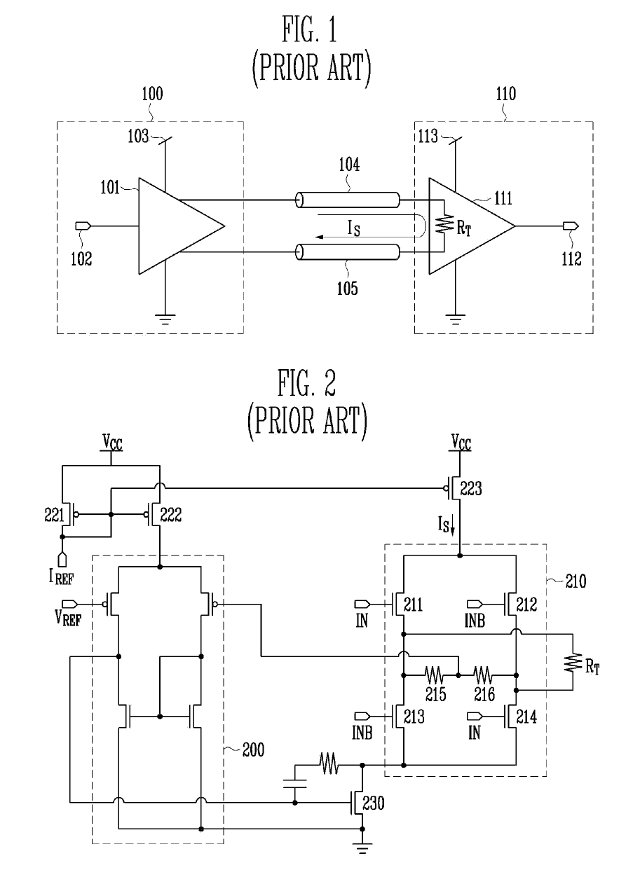

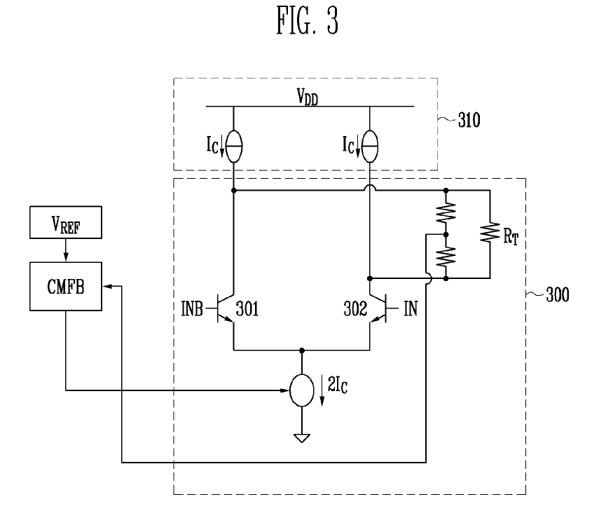

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. Therefore, the following embodiments are described in order for this disclosure to be complete and enabling to those of ordinary skill in the art.

FIG. 3 is a circuit diagram of a high-speed low-voltage differential signal (LVDS) driver according to an exemplary embodiment of the present invention.

Referring to FIG. 3, a current source circuit 310 for supplying current to a differential driving circuit 300 in a CMOS process is formed of double current sources (DCSs). In the differential driving circuit 300, the FETs used in the conventional driving circuit are replaced by bipolar transistors 301 and 302.

Owing to this structural feature, it is possible to minimize parasitic resistance regardless of a size of the device included in the differential-signal driving circuit 300 by providing a smaller sized differential-signal driving circuit 300.

In addition, it is possible to operate the differential-signal driving circuit 300 at a lower power source voltage (e.g., 1.8V) by reducing the number of devices between the power source voltage terminal and the ground voltage terminal.

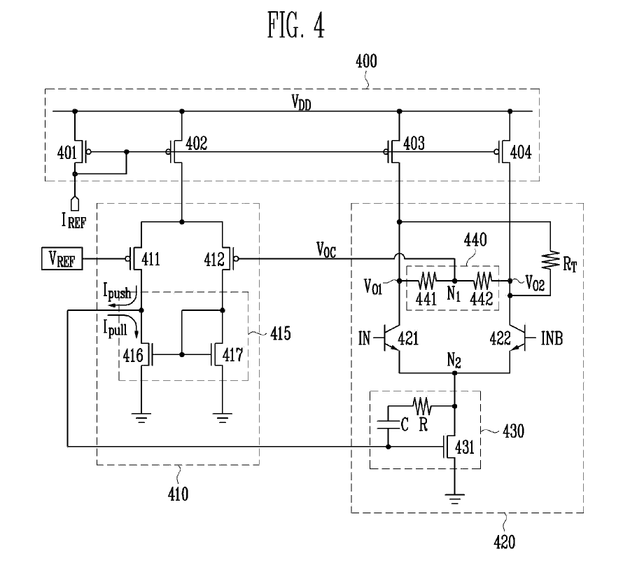

FIG. 4 is a detailed circuit diagram of the high-speed LVDS driver according to the exemplary embodiment of the present invention. Referring to FIG. 4, the high-speed LVDS driver comprises a current source circuit 400, a common mode feedback (CMFB) circuit 410, and a differential-signal driving circuit 420.

In the current source circuit 400, first through fourth PMOS transistors 401, 402, 403, and 404 constitute a current mirror. The second PMOS transistor 402 supplies current to the CMFB circuit 410. The third and fourth PMOS transistors 403 and 404 supply current to the differential-signal driving circuit 420 in the form of a differential cascode switch (DCS).

The CMFB circuit 410 compares a common mode voltage V_{OC} with a reference voltage V_{REF}, providing a current I_{PUSH} to a current node N₂, or accepting a current I_{PULL} from the current node N₂.

The CMFB circuit 410 comprises a fifth PMOS transistor 411 for receiving the reference voltage V_{REF}, a sixth PMOS transistor 412 for receiving the common mode voltage V_{OC}, and a current mirror 415. A first end (source) of the fifth PMOS transistor 411 is connected to a second end (drain) of the second PMOS transistor 402. A first end of the sixth PMOS transistor 412 is connected to the second end (drain) of the second PMOS transistor 402.

The current mirror 415 comprises first and second NMOS transistors 416 and 417. A first end (drain) of the first NMOS transistor 416 is connected to a second end (drain) of the fifth PMOS transistor 411. A second end (source) of the first NMOS transistor 416 is connected to the ground. A first end (drain) and a gate of the second NMOS transistor 417 are commonly connected to a second end (drain) of the sixth PMOS transistor 412. A second end (source) of the second NMOS transistor 417 is connected to the ground.

The differential-signal driving circuit 420 receives differential input signals IN and INB and then generates a differential output signal from switching a difference between the differential input signals IN and INB through the terminal resistor R_{T}.

The differential-signal driving circuit 420 comprises a first bipolar transistor 421 for supplying current from the third PMOS transistor 403 and receiving the input signal IN, and a second bipolar transistor 422 for supplying current from the fourth PMOS transistor 404 and receiving the input signal INB.

The effect of using the first and second bipolar transistors 421 and 422 without using field effect transistors to switch elements of the differential-signal driving circuit is as follows.

It is generally known that the rated current capacity of field effect transistors increases in proportion to a device size (W/L ratio), while the collector current of bipolar transistors exponentially increases in proportion to a base-emitter voltage. Therefore, it is not necessary to give too much regard to a device's size when using the bipolar transistors as the differential switching devices.

Further, as the field effect transistor has substantially indefinite gate input resistance, it has a characteristic of low power consumption due to a very high input resistance and an input bias current of almost 0 mA. Otherwise, the bipolar transistor has higher transconductance than the field effect transistor, and so the bipolar transistor has excellent current drivability.

Thus, if the field effect transistors are used in the differential-signal driving circuit, there is fluctuation of a static current (3.5˜12 mA) in applications which require a very large size (W/L) to minimize a voltage over the field effect transistor in the differential-signal driving circuit.

Hence, the bipolar transistors, as switching devices instead of the field effect transistors in the differential-signal driving circuit, are advantageous in terms of high current drivability, chip-area minimization regardless of current amount, and operation speed of the circuit.

As illustrated in FIG. 4, the differential-signal driving circuit 420 also includes a third NMOS transistor 430 connected to the first and second bipolar transistors 421 and 422 through a current node N₂ and interposed between the current node N₂ and the ground, and receiving a bias voltage through its gate.

The differential-signal driving circuit 420 further comprises a resistive divider (or voltage divider) 440 that includes a first resistor 441 connected between a first output node V_{O1} and a common node N₁, and a second resistor 442 connected between a second output node V_{O2} and the common node N₁. The resistive divider 440 generates a common mode voltage V_{OC} of 1.2V to the common mode N₁.

The resistive divider 440 is designed to have as large a resistance as possible in order to inhibit a large amount of current, while not affecting impedance matching between the transmission stage and the transmission line. Additionally, in transmitting an incident wave, output resistance of the switching transistors (i.e., the bipolar transistors) is set to, for example, 100Ω, which is a specific impedance of the transmission line to match impedance therebetween.

The differential-signal driving circuit 420 also includes a Miller-effect compensation circuit 430 where a first end (drain) of a third NMOS transistor 431 is connected to its gate through an RC coupling. The Miller-effect compensation circuit 430 enables a low frequency pole that stabilizes an operation of the CMFB circuit 410. Moreover, it is possible for the common mode voltage V_{OC} to obtain a single output wave (refer to 501 and 502 of FIG. 5) and a low voltage swing (refer to 503 of FIG. 5) of ±400 mV on the terminal resistor R_{T} of 100Ω.

Hereinafter, an operation of the differential-signal driver according to the present invention will be described.

A condition for stably operating the differential-signal driving circuit 420, i.e., a condition for properly maintaining the common mode voltage V_{OC} in the differential-signal driving circuit 420, is that a sum of currents flowing through the third and fourth PMOS transistors 403 and 404 is the same as a sum of currents flowing through the first and second bipolar transistors 421 and 422.

If the sum of currents flowing through the third and fourth PMOS transistors 403 and 404 is larger than the current of the third NMOS transistor 413, the first NMOS transistor 416 of the CMFB circuit 410 brings the second additional current I_{PULL} via the current gap from the current node N₂. Then, at the output nodes V_{O1} and V_{O2}, the sum of currents flowing through the third and fourth PMOS transistors 403 and 404 is equal to the sum of currents flowing through the first and second bipolar transistors 421 and 422, which makes the common mode voltage of the output nodes V_{O1} and V_{O2} stabilized between the power source voltage VDD and the ground.

Otherwise, if the sum of currents flowing through the third and fourth PMOS transistors 403 and 404 is smaller than the sum of currents flowing through the first and second bipolar transistors 421 and 422, the first additional current I_{PUSH} is supplied from the fifth PMOS transistor 411 through the current node N₂. Then, the sum of currents flowing through the third and fourth PMOS transistors 403 and 404 is equal to the sum of currents flowing through the first and second bipolar transistors 421 and 422.

In the CMFB circuit 410, the fifth PMOS transistor 411 has the same current amount as the sixth PMOS transistor 412 when the common mode voltage V_{OC} matches to the reference voltage V_{REF}. And, the first and second NMOS transistors 416 and 417 of the current mirror 415 connected to the fifth and the sixth PMOS transistors 411 and 412 also have the same current amount.

As the first and second NMOS transistors 416 and 417 of the current mirror 415 must always have the same current amount therethrough, and an extra current flows toward the current node N₂ of the differential-signal driving circuit 410, as the first additional current I_{PUSH}, when the current of the fifth PMOS transistor 411 is larger than that of the sixth PMOS transistor 412, because the common mode voltage V_{OC} is lower than the reference voltage V_{REF}.

On the contrary, when the current of the fifth PMOS transistor 411 is smaller than that of the sixth PMOS transistor 412, because the common mode voltage V_{OC} is higher than the reference voltage V_{REF}, the second additional current I_{PULL} is supplied to the first NMOS transistor 416 from the current node N₂ via the current gap. Thereby, the first NMOS transistor 416 has the same current amount as the second NMOS transistor 417.

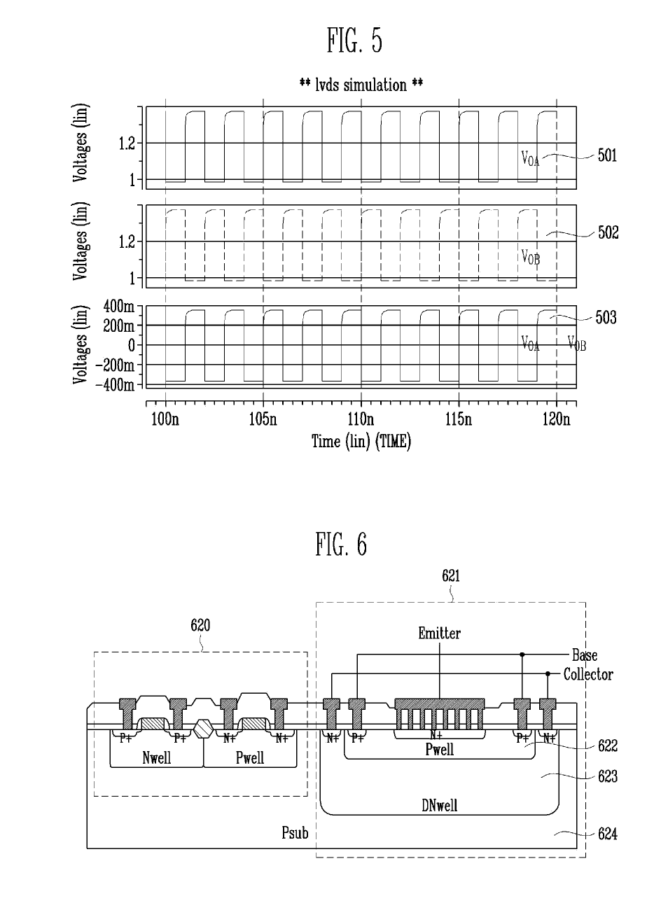

FIG. 6 is a sectional diagram of a bipolar transistor fabricated by the exemplary embodiment of the present invention.

In fabricating the bipolar transistor 621 according to the exemplary embodiment of the present invention, a P-type well 622 is formed after settling a deep N-type well 623 in a substrate 624 in order to isolate the bipolar transistor 621 from a field effect transistor 620 in potential. Thereby, the bipolar transistor 621 can be driven independently from a potential of the substrate 624 without additional isolation means. Thus, it is possible to fabricate the bipolar transistor 621 without additional processes, to thereby not affect electrical characteristics of the field effect transistor 620 that is disposed in the same substrate 624. As a result, it is permissible to conduct a BiCMOS fabrication process by using the same masks as the field effect transistor, without an additional mask in a CMOS process.

As described above, the present invention offers a differential-signal driving circuit capable of operating at a high speed at a low voltage (e.g., 1.8V).

And, the differential-signal driving circuit according to the present invention operates at high speed by using the bipolar transistors as switching devices, instead of the field effect transistors therein.

Moreover, the present invention provides a differential-signal driving circuit including bipolar transistors that can be fabricated without an additional mask in a CMOS process.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method of fabricating a bipolar transistor and a field effect transistor on a substrate, the method comprising the steps of:
forming a first-conductive first well region of the bipolar transistor deeper than a first-conductive third well region and a second-conductive fourth well region of the field effect transistor; and
forming a second-conductive second well region, which is formed in the first well region, shallower than the third and fourth well regions,
wherein the bipolar transistor has a different potential than the field effect transistor.

2. A high-speed low-voltage differential signal driver comprising:
a differential-signal driving circuit for switching input differential signals and outputting a common mode voltage through first and second output nodes; and
a common-mode feedback circuit for providing a predetermined current to the differential-signal driving circuit or receiving a predetermined current from the differential-signal driving circuit in response to the common mode voltage,
wherein the differential-signal driving circuit comprises a common-mode voltage output circuit for connecting the first output node to the second output node and generating the common mode voltage of the differential-signal driving circuit, and
wherein the differential signals are received through two bipolar transistors.

3. The high-speed low-voltage differential signal driver of claim 2, wherein the common-mode voltage output circuit comprises first and second resistors between the first and second output nodes, and outputs the common mode voltage through an intermediate node connecting the first resistor to the second resistor.

4. The high-speed low-voltage differential signal driver of claim 2, wherein the differential-signal driving circuit comprises:
a first bipolar transistor having a first end connected to the first output node and a second end connected to a current node, and receiving the first differential input signal through a base;
a second bipolar transistor having a first end connected to the second output node and a second end connected to the current node, and receiving the second differential input signal through a base; and
a third NMOS transistor having a first end connected to the current node, a gate coupled to the common-mode feedback circuit, and a second end connected to a ground.

5. The high-speed low-voltage differential signal driver of claim 4, wherein the common-mode feedback circuit comprises:
a fifth PMOS transistor having a first end receiving a current, a gate receiving a reference voltage, and a second end connected to the current node; and
a sixth PMOS transistor having a first end receiving a current, a gate coupled to the intermediate node, and a second node connected to a current mirror,
wherein the current mirror comprises:
a first NMOS transistor having a first end connected to the current node, a gate coupled to the second end of the sixth PMOS transistor, and a second end connected to the ground; and
a second NMOS transistor having a first end and a gate which are coupled to the second end of the sixth PMOS transistor, and a second end connected to the ground.

6. The high-speed low-voltage differential signal driver of claim 4, wherein the common-mode feedback circuit supplies a predetermined current to the current node of the differential-signal driving circuit when the common mode voltage is lower than the reference voltage.

7. The high-speed low-voltage differential signal driver of claim 4, wherein the common-mode feedback circuit is supplied with a predetermined current from the current node of the differential-signal driving circuit when the common mode voltage is higher than the reference voltage.

8. The high-speed low-voltage differential signal driver of claim 4, wherein the common-mode feedback circuit comprises a Miller-effect compensation circuit including a third resistor and a capacitor that connect the current node to the gate of the third NMOS transistor.

9. The high-speed low-voltage differential signal driver of claim 2, wherein the bipolar transistor and the field effect transistor are formed on the same substrate, but have different potentials from each other, and
wherein the first-conductive first well region of the bipolar transistor is formed deeper than the first-conductive third well region and the second-conductive fourth well region of the field effect transistor, and the second-conductive second well region formed in the first well region is formed shallower than the third and fourth well regions.
